(19) United States
(12) Patent Application Publication
(10) Pub. No.: US 2015/0228830 A1
(43) Pub. Date: Aug. 13, 2015

(54) SOLAR ELEMENT COMPRISING RESONATOR FOR APPLICATION IN ENERGETICS

(71) Applicant: VYSOKÉ UCENI TECHNICKÉ V BRNÉ, Brno (CZ)

(72) Inventor: Pavel Fiala, Brno (CZ)

(21) Appl. No.: 14/427,898

(22) PCT Filed: Oct. 22, 2012
(86) PCT No.: PCT/CZ2012/000105

§ 371 Date: Mar. 12, 2015

(30) Foreign Application Priority Data
Sep. 14, 2012 (CZ) 2012-636

(51) Int. Cl. H01L 31/055

(52) U.S. Cl. CPC H01L 31/055

(57) ABSTRACT

A solar element including a basic resonator arranged on a dielectric structure that is constituted by an area (5) with minimum electromagnetic damping, whose upper plane forms the plane of incidence (3). The area (5) with minimum electromagnetic damping is transparent in relation to the incident electromagnetic wave; the area is limited by the boundaries (6) of variations in material properties, and at least one 2D-3D resonator (4) is surrounded by the dielectric (10) and configured in the dielectric structure. The area (5) with minimum electromagnetic damping is coupled with at least one other area (20) exhibiting a different resonance frequency of the basic resonator, and the system is terminated either in the free space or by a solar element (system) intended to absorb the entire amount of the remaining energy provided by the incident electromagnetic wave.

### TECHNICAL FIELD OF THE INVENTION

The invention relates to a solar system with elements including a resonator characterized by a high rate of efficiency in transforming the energy of light to electric energy. The system includes a structure located between a pair of electrodes with the aim to utilize the element for high-efficiency transformation of the energy of light to electric energy.

### STATE OF THE ART

In contemporary photovoltaics, more than fifty-year-old principles of transforming solar electromagnetic radiation or waves (wideband electromagnetic radiation within the wavelength range of 100 nm to 10000 nm) are generally applied. The solar cells are composed of two semiconductor layers (with silicon being the typical material) located between two metal electrodes. One of the layers (an N-type material) comprises a multitude of negatively charged electrons, whereas the other layer (a P-type material) exhibits a large number of “holes” definable as void spaces that easily accept electrons. The devices transforming electromagnetic waves to a lower-frequency electromagnetic wave, or a direct component, are known as transvertors/converters. For this purpose, semiconductor structures with different concepts and types of architecture are applied, respecting only experimental results of the electromagnetic wave transformation effect:

The antennas, detectors, or structures designed to date are not tuned into resonance; the applied semiconductor structures face considerable difficulty in dealing with emerging stationary electromagnetic waves, and the efficiency of energy transformation has to be increased via additional measures.

Similar solutions utilize the principles of antennas or the transformation of a progressive electromagnetic wave to another type of electromagnetic radiation (namely a progressive electromagnetic wave having a different polarization or a stationary electromagnetic wave) and its subsequent processing. Certain problems occur in connection with the incident electromagnetic wave and its reflection as well as in relation to the broad-spectrum character of solar radiation. In general, it is not easy to construct an antenna capable of maintaining the designed characteristics in the wide spectrum for the period of several decades.

A solution has been proposed in which a single-layered system of tuned structures is applied to exploit The incident solar radiation; the system is based on a resonant mode semiconductor.

The Czech patent application PV 2011-42 contains the description of a photovoltaic element including a resonator and arranged on a semiconductor structure. The structure is formed by an area without electromagnetic damping, whose upper plane constitutes the incidence plane, and an area with electromagnetic damping; both the areas are bounded by virtual (assumed) boundaries of material property changes, and at least one 2D-3D resonator is surrounded by a dielectric and arranged in the semiconductor structure. The area ,with electromagnetic damping borders on a relative electrode. The disadvantage of the solution consists in that, upon the incidence of an electromagnetic wave having high power density in the infrared radiation spectra A, B, C, and D, the semiconducting substrate may overheat. This problem then results in the reduction of operating life or even complete destruction of the element.

### SUMMARY OF THE INVENTION

The invention is aimed to propose a new architecture of a solar element having a resonator arranged on a dielectric structure. Based on the utilized construction technique, the element resonates and produces high-value components of the electric and magnetic fields in such a manner that these components are utilizable and processible by means of the Well-known technology based on classical electronic elements.

The above-mentioned drawbacks are eliminated by a solar element including a resonator and arranged in a structure; the element is characterized in that it comprises a layered dielectric structure composed of an area with minimum electromagnetic damping, whose upper plane constitutes the incidence plane. The layered dielectric structure, permeable for an electromagnetic wave, is defined by the boundaries of material property changes, and at least one 2D-3D resonator is arranged in the area with minimum electromagnetic damping, where the 2D part of the resonator is arranged in the incidence plane, with the related 3D part located in the dielectric. The area with minimum electromagnetic damping is coupled with at least one area having a different resonance frequency. This area is defined by the boundaries of material property changes, and at least one 2D-3D resonator is arranged in the area exhibiting a different resonance frequency. While the 2D part of this resonator is arranged in the incidence plane, its 3D portion is located in the dielectric, and the last structure having a different resonance frequency is coupled with the solar system in the direction of the electromagnetic wave propagation.

The creation of high-value components of the electric and magnetic fields can be realized conveniently when the 2D-3D resonator is composed of two parts, of which the first (2D) part is constituted by a transformational element arranged on the incidence plane and consisting of a pair of electrodes in the form of coupled conductors, while the second (3D) part is constituted by a dielectric and a reflector arranged both inside the area without electromagnetic damping and inside the area through which the electromagnetic wave passes in a no-loss manner; the transformational element is further arranged on the dielectric, upon which the reflector is placed orthogonally.

The invention utilizes the spectrum of solar radiation in which the electromagnetic wave power flux density (W/m²) is high. Within the presented invention, the solar element in the form of a 2D-3D resonator arranged on a layered dielectric structure is, for the selected portion of the spectrum, tuned to the frequency of the incident EMG wave. The element is tuned in such a manner that it focuses on areas exhibiting high values of power spectral density (such as the infrared radiation areas A, B, C, D); simultaneously, another 2D-3D resonator is tuned to a different frequency of the selected region of the spectrum. This resonator then follows the preceding 2D-3D resonator in the direction of progress of the incident electromagnetic wave. Through such inclusion of other resonators arranged in layers or areas (even though theoretically an infinite number of resonators can be included, the real number remains within several hundreds of these elements), a system of 2D-3D resonators could be built depending on the geographical and climatic conditions; thus, it is possible to exploit the incident electromagnetic wave to acquire the maximum of energy for subsequent conversion into electric energy. In comparison with the currently applied solar and photovoltaic elements, the manufacturing technology and design of the resonators described herein provide for long operating life and allow high thermal differences. The concept realized within the described invention is characterized by top efficiency achieved in transforming the energy of light/thermal energy into electric energy.

The main advantage of the newly constructed solar element consists in the manner of its composition, namely in the layered dielectric structure. This structure is formed by individual areas of the dielectric material, and each of these areas with dielectric properties contains a 2D-3D resonator. The thus designed arrangement of the layered dielectric structure generates a minimum amplitude size and the phase of the backward electromagnetic wave propagating in the direction of the incident electromagnetic wave emitted by a source such as the Sun. The solar element exploits the necessary portion of energy, and the actual layered dielectric structure will not heat up thanks to the effects brought upon the solar element by the incident or the incident and back-reflected electromagnetic wave. The 2D-3D resonator is designed in such a manner that the electromagnetic wave passing through the dielectric structure propagates further behind the 2D-3D resonator to other areas with 2D-3D resonators and, at the end of the dielectric structure, into the free space or a solar system capable of harvesting the remaining energy in the form of residual heat, an electromagnetic wave, or light. Thus, the resonator behaves like an ideal impedance-matched antenna or an ideal energy converter for the proposed wide and arbitrarily variable frequency spectrum.

The layered dielectric structure contains several components described in the following section of the text. Firstly, it is necessary to specify the area with minimum electromagnetic damping, which is bounded by the planes of variation in material properties; this area with minimum electromagnetic damping is intended to harvest a portion of the energy of the incident electromagnetic wave on its boundary. The rest of the energy is left to leave the area, with minimum loss. Then, at least one 2D-3D resonator is arranged on the incidence plane which, in this case, is identical with the plane of variation in material properties. These parts ensure optimal processing of the electromagnetic wave; the processing is realized in such a manner that there occurs minimal reflection of the electromagnetic wave towards the 2D-3D resonator. Behind the area with minimum electromagnetic damping, which ends at the plane of variation in material properties, there follows another area; this area exhibits a different resonance frequency of the 2D-3D resonator and is arranged in the direction of the electromagnetic wave propagation. The area contains at least one 2D-3D resonator tuned to a frequency different from the first resonator arranged in the area with minimum electromagnetic damping. In the described manner, the structure is composed within the solar system; the system can be terminated by the last solar element, and the electromagnetic wave leaves the system into the free space. Alternatively, the last area of the solar element may consist in a classical component of the solar system, which will transform or otherwise exploit the rest of the electromagnetic wave energy by converting it into a useful form of energy to be applied as a source of heat, light, or electric energy.

Importantly, the designed solar element having a resonator arranged on a dielectric structure does not utilize the material to secure the generation of an electric charge, but rather uses the characteristics of the structure to set suitable conditions for the incidence of an electromagnetic wave and its transformation to a stationary form of the electromagnetic field.

Thanks to the composition of selectively tuned areas within the system, the system behaves in such a manner that it exploits with maximum efficiency the energy incident in the form of an electromagnetic wave according to its representation in the frequency spectrum (spectral power density distribution) of the wave. This enables us —in comparison with cases when the resonators or their periodic group are not modified as described above—to comprise and exploit the desired frequency spectrum of the incident electromagnetic wave using a markedly lower number of variants of tuned structures within the complex of the designed structure and system.

Based on the presented invention, the described solution allows the adaptation of individual solar element areas arranged in the resulting structure to density conditions of the incident electromagnetic radiation as present at the concrete location where the elements are applied. In consequence of this characteristic, it is possible to utilize (harvest) the maximum of the incident electromagnetic radiation and to profit from the change of the radiation to the required form of energy that facilitates further application (for example, as an electric energy source or generator). The designed solar elements including resonators are embedded in panels which, when interconnected, create photovoltaic (solar) fields.

A significant advantage of the introduced solution consists in the fact that the solar element construction enables us to set up various (optimum) variants of the solar system according to the climatic conditions or solar activity. While one of the solar element structures containing several areas fitted with 2D-3D resonators can be tuned to one resonance frequency corresponding to the selected power spectral density (realized in forms such as a foil), another structure of solar elements can be tuned to a different selected frequency of power spectral density. The structures are arranged one after another in the direction of the electromagnetic wave progressing from the source. Therefore, it is possible—for the given geographic area, solar activities, or electromagnetic wave source—to set a system facilitating maximum exploitation of the electromagnetic wave as a form of incident energy.

The thus composed solar elements can be manufactured or assembled in a factory or set up directly at the proposed location from the supplied kit.

### BRIEF DESCRIPTION OF THE DRAWINGS

The principle of the invention will be clarified through the use of drawings, where:

FIG. 1 describes the basic arrangement of a solar element with a 2D-3D resonator and indicates the configuration in the system;

FIG. 2 illustrates an exemplary embodiment of a solar element including a system of 2D-3D resonators and connecting components arranged on a semiconductor structure and indicates the arrangement of another solar element tuned to a different frequency;

FIG. 3 shows a schematic view of a 2D-3D resonator arranged in a dielectric;

FIG. 4 represents the configuration of a 2D-3D resonator and a reflector;

FIG. 5 provides a view from the direction of the EMG wave incidence on the 2D resonator and describes the partial spatial arrangement of the 2D-3D resonator in the dielectric as well as the position of the reflector area within the solar element dielectric;

FIG. 6a illustrates the axonometric view of the resonator (formed by the reflector) above which the dielectric and a transformational component are arranged;

FIG. 6b shows a lateral view of the resonator;

FIG. 7a represents the connection of the transformational component with a nonlinear component in the forward direction;

FIG. 7b describes the connection of the transformational component with the nonlinear component in the reverse direction;

FIG. 8 shows the resonant circuit connection (the circuit consists of a solar element and related electronics).

### EXEMPLARY EMBODIMENT OF THE INVENTION

The principle of the construction of a solar element with a resonator arranged on a semiconductor structure will be clarified by but not limited to the examples provided below.

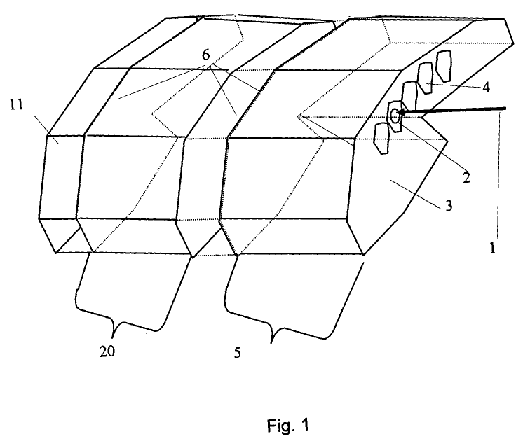

The basic version of a solar element with a 2D-3D resonator arranged on a dielectric is provided in FIG. 1. This form of the solar element includes a layered dielectric structure. This structure is formed by the area 5 with minimum electromagnetic damping; the structure is limited by the boundaries 6 of material property changes and by the area 20 exhibiting a different resonance frequency. Furthermore, the area 5 with minimum electromagnetic damping includes at least one 2D-3D resonator 4. At the location of the incidence plane 3 on the surface of the area, the 2D part of the resonator 4 is arranged; the 3D part of the resonator occupies a portion of the area 5 with minimum electromagnetic damping. The 3D part, in this case, is limited by the boundary 6 of material property changes. After the area 5 with minimum electromagnetic damping in the direction of EMG wave propagation, which is limited by the incidence plane 3 and the boundary 6 of material property changes, there follows another area 20 exhibiting a different resonance frequency of the 2D-3D resonator. After the last area 20 exhibiting a different resonance frequency of the 2D-3D resonator, either the free space or a solar system is coupled to the area 11.

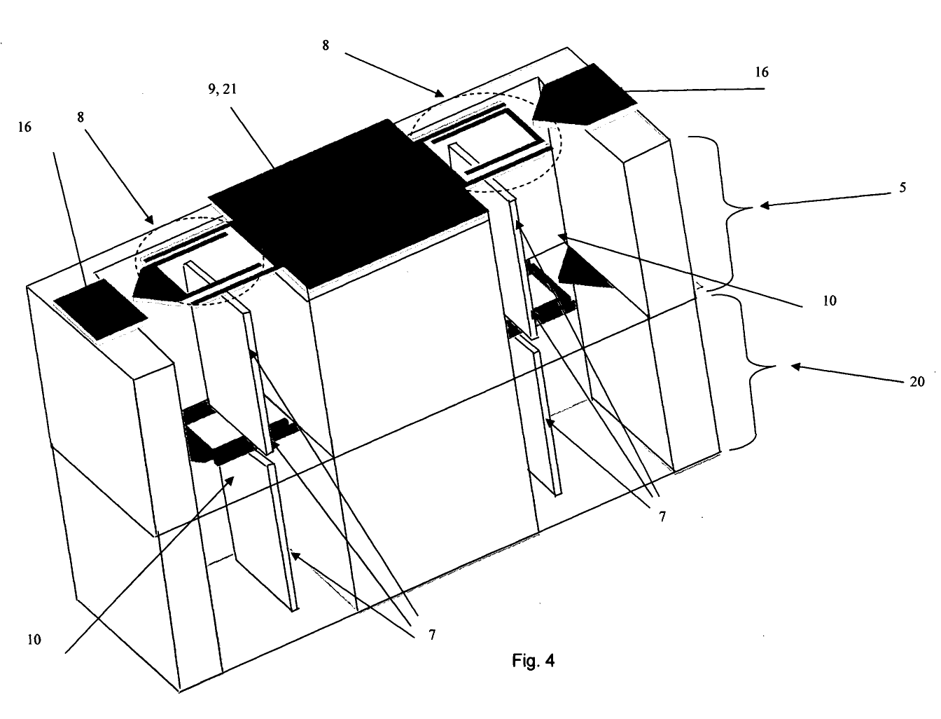

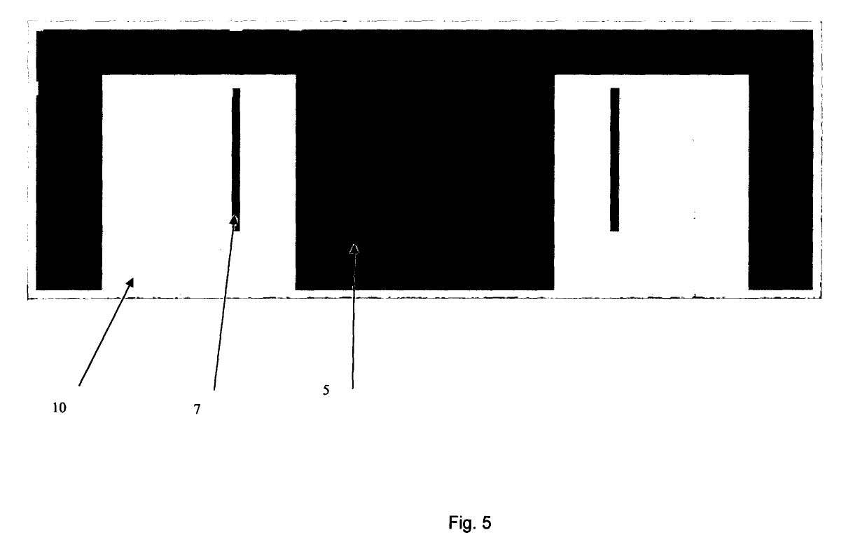

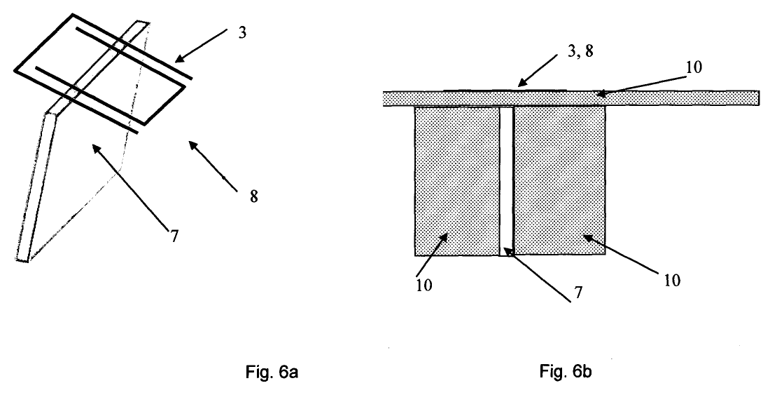

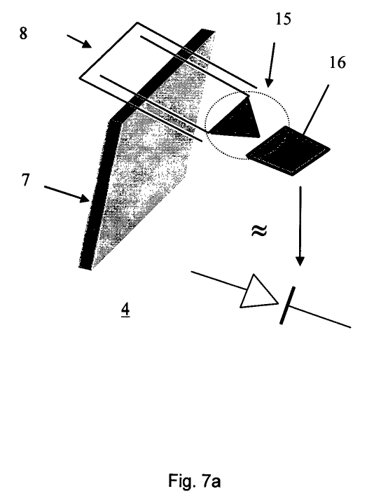

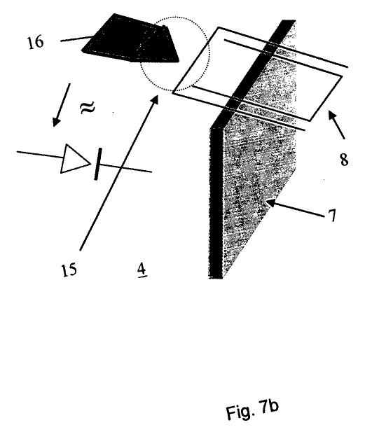

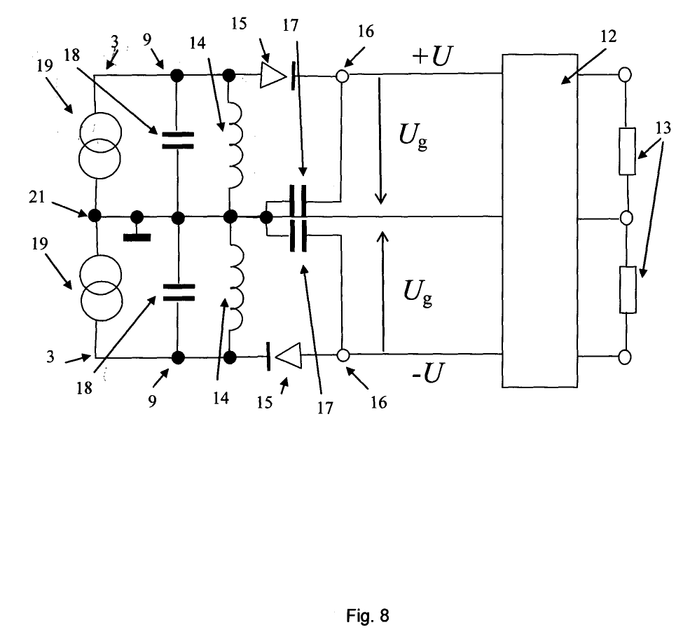

The actual 2D-3D resonator 4 is described in FIGS. 4, 6a and 6b. This version of the 2D-3D resonator 4 consists of a transformational component 8 and a reflector 7, between which the dielectric 10 (such as an insulant) is arranged, with the transformational component 8 constituted by a pair of electrodes in the form of mutually arranged, coupled conductors surrounded by the dielectric 10. Furthermore, the transformational component 8 is arranged on the dielectric 10, upon which the reflector 7 is placed orthogonally. FIG. 5 shows the arrangement of the dielectric 10 in the layered structure. The 2D-3D resonator 4 produces electric current or voltage, which is conducted by the help of a nonlinear component 15 to the connecting element 16; this situation can be seen in FIGS. 7a and 7b, where both types of the nonlinear component 15 polarization are described.

FIG. 8 represents an electrical alternate diagram of the solar element. The variants concerned are principally a one-way or two-way rectifier, a shaper, or a signal filter. These types of connection are widely known. A source 19 of alternating current or voltages caused by the induction from an electromagnetic wave is connected parallelly to the first capacitor 18 and the inductor 14, which in the connection are constituted by a condenser and a coil. These components then create a tuned alternating circuit, which is tuned to the characteristics and parameters of the incident electromagnetic wave and which resonates. The nonlinear element 15 shapes the signal on the resonant circuit; this signal is then filtered (rectified) to a further utilizable shape. As the next step, connection to the second capacitor 17 is realized; in the connection, the capacitor is constituted by a condenser. Also, in the connection, the connecting components 16 are indicated. These components 16 exhibit electric voltage +U, −U. If a selected electrical load 13 in the form of impedance Z is connected to the connecting components 16 (such as clamps), a variation in the resonant circuit occurs and the resonator may change its characteristics to such an extent that it will not be in a suitable resonance mode. Therefore, a device 12 is introduced before the electrical load 13. With any loading by electrical impedance Z on its output, this device will cause the situation when, on the output, the resonator with the nonlinear component 15 and the second capacitor 17 is loaded by one and the same value of impedance Zi, which will not change the set mode of the resonator.

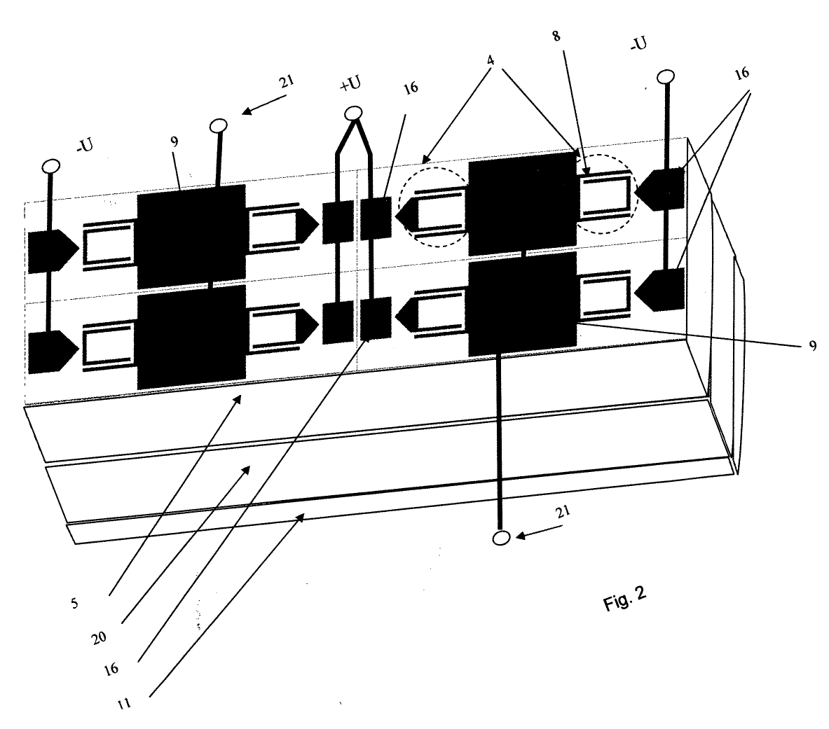

The function (or operation) of the solar element, which includes a 2D-3D resonator 4 arranged on a layered dielectric structure, is as follows: An electromagnetic wave 1 within the wavelength range of 100 nm to 100000 nm impinges at the wave incidence point 2 on the incidence plane 3 of the area 5 with minimum electromagnetic damping. The 2D-3D resonator 4 is periodically repeated also in individual areas 20 having different resonance frequencies (as described in FIG. 1 and FIG. 2). In the incidence plane 3 of area 5, the formation of at least one 2D-3D resonator 4 is arranged. This resonator may operate (perform its function) individually; alternatively, we can realize an interconnection between the resonators, thus creating a field of periodically repeating solar elements. In the incidence plane 3, these elements are connected parallelly or in series, with the formation of at least two 2D-3D resonators 4 on one solar element appearing to be an advantageous solution. These resonators are interconnected by means of a connecting element 9. The first area 5 with minimum electromagnetic damping in the direction of the electromagnetic wave incidence is tuned to the resonance frequency f₁ from the domain of the incident electromagnetic wave spectrum; after this area, another area 20 having a different resonance frequency f₂ is included in the direction of the progressing electromagnetic wave. Thus, the progress occurs of other N up to the order of hundreds or thousands of areas 20 exhibiting different resonance frequencies, and a system is created; also, there holds that the resonance frequencies of f₁ to fₙ do not have to be repeated in the layers, and this rule ensures the maximum exploitation of energy of the incident electromagnetic wave.

An electromagnetic wave 1. impinges at the point of incidence 2 on the incidence plane 3. Here, the electric and magnetic components of the electromagnetic wave 1 decompose and form the maxima of intensities of the electric and magnetic fields. This process is realized thanks to the designed shape of the reflector 7, which can be a thin layer, a cuboid, a pyramid, a cone, a toroid, or a sphere of their combination, parts, penetration. The surface of the reflector 7 may be formed by a layer of a dielectric material, metal, or a combination and shape variety of both (the components being part of the 2D-3D resonator 4). In order for the above-mentioned maxima of intensities to add up arithmetically (superpone) when a connection is realized of two periodically repeated 2D-3D resonators 4, these resonators are connected via a connecting element 9 (as described in FIG. 2). This figure shows an example of the proposed solar element having a 2D-3D resonator arranged in a dielectric structure, where two 2D-3D resonators 4 are arranged at the location of the incidence plane 3. These resonators are periodically repeated on other dielectric structures 5; also, the 2D-3D resonators 4 are interconnected by means of the connecting components 9.

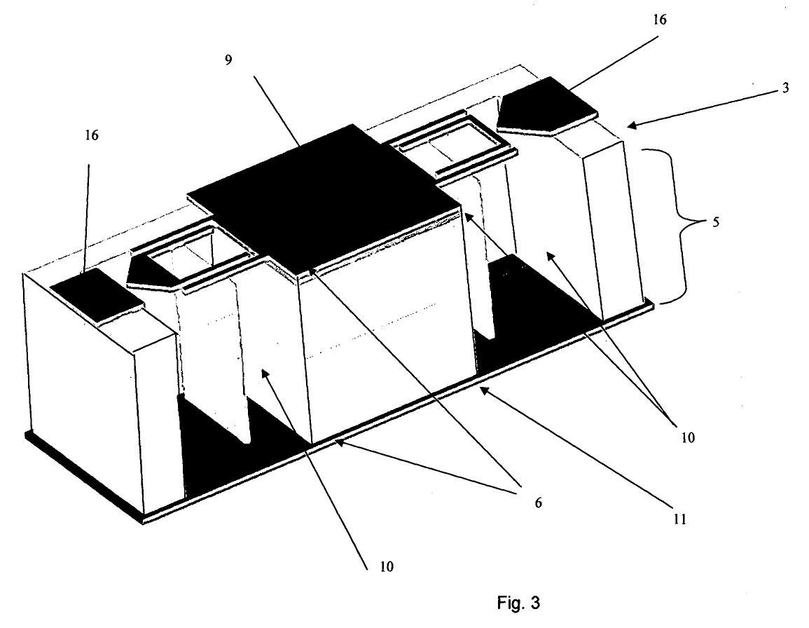

An exemplary embodiment of a solar element including a 2D-3D resonator 4 and arranged in a dielectric is described in FIG. 3. This version of the 2D-3D resonator 4 is arranged in a layered dielectric structure. The area 5 with minimum electromagnetic damping is limited by the boundaries 6 of the material property changes. Mutual arrangement (configuration) of individual parts of the solar element is shown in FIG. 4. The 2D-3D resonator 4 consists of a transformational component 8 (which is composed of a pair of electrodes in the form of coupled conductors), reflector 7, and a dielectric 10: The 2D-3D resonator 4 is further embedded in the layered dielectric structure; the geometry is designed in relation to the wavelength of the incident electromagnetic wave, namely in such a manner that the thickness of the dielectric structure will be minimally ¼ of the wavelength of the lowest frequency of the incident electromagnetic radiation. The proposed geometry design will ensure the resulting resonance characteristic.

After impinging on the incidence plane 3, the electromagnetic wave permeates through the layered dielectric: structure. On the surface of the structure, at the location of the incidence plane 3, the 2D part of the resonator 4 is arranged, whereas the 3D part occupies a portion of the area 5 having minimum electromagnetic damping (as illustrated in FIGS. 3 or 4). The area 5 with minimum electromagnetic damping is instrumental towards setting the conditions of the maxima of electrical and magnetic components in the electromagnetic wave incidence plane 3. In this respect, the layered dielectric structure is designed in such a manner that the progressing electromagnetic wave on the layered dielectric structure could couple and create a resonant area with the maximum resonance on the incidence plane 3. The area 5 with minimum electromagnetic damping is equipped with a relative electrode 21. The electromagnetic wave further progresses behind the area 5 with minimum electromagnetic damping; the wave progresses in such a manner that it creates only a minimal reflected wave. The dimensions of the area 5 with minimum electromagnetic damping are selected to be, in the least, equal to or greater than one quarter of the wavelength of the incident electromagnetic wave in relation to the relative permittivity of dielectric 1 (for example, both layers may show the thickness of 10 μm for the selected type of material).

Through achieving the resonant state, there occurs—in at least one solar element within the group of periodically repeating elements that are ordered one after another in the direction of the incident electromagnetic wave—a multiple increase of amplitudes of the original incident electromagnetic wave; for the assumed wavelength of the electromagnetic wave 1 impinging on the incidence plane 3 of the dielectric structure 5, we can obtain an electric voltage applicable for further processing by electronic circuits 12 that manage the performance and mode of the periodic/layered structure designed for energy harvesting (energy exploitation, “power management”).

A high-quality conductor or dielectric is applied as the material of conductive paths formed in the incidence plane 3, on which the 2D part of the resonator 4 is arranged; the same high-quality conductor is also used for the transformational element 8, the connecting element 9 material, and the nonlinear element 15 material. The conductor exhibits different relative permittivity with respect to the relative permittivity of the minimum electromagnetic damping area 5. The area 5 with minimum electromagnetic damping is formed by a combination of the dielectric 10 and a conductive and/or semi-conductive material. The design of the resonator, its arrangement, and the selection Of the materials were all realized in such a manner that, in the area 5 with minimum electromagnetic damping, the reflection coefficient is less than 0.5 from the interval of <−1,1>.

The designed dielectric structure of the solar element included in the system operates in the resonant state, which enables us to advantageously obtain on the resonator 4 multiple (1-10000) values of amplitude of the electric component of the incident electromagnetic wave 1. The proposed periodic arrangement of the solar system facilitates operation in the resonant mode for frequencies f within the range of 0.1 THz to 5000 THz of the incident electromagnetic wave spectrum.

The classical solution using antennas and standard resonant circuits usually achieves only the ratio of selective properties, and it is not possible to design this solution for the above-stated frequency range of the incident electromagnetic wave. The approach proposed in this document, thanks to the application of a higher number of tuned elements in the entire photovoltaic/solar system, enables us to achieve energy transformation in the above-specified frequency range. This condition can be advantageously utilized for the design of an optimum layered dielectric structure and for approaching the ideal state of 100% exploitation rate, or transformation of the electromagnetic wave 1 incident on the elements to the generator output. Thus, the proposed approach can be applied to facilitate permanent use of the designed system characterized by high efficiency, operating life, and independence of thermal parameters of the realized systems.

A necessary prerequisite for the utilization of the basic element (at the very minimum) as an electric energy source consists in connecting the electronic external circuit 12, which enables us to achieve the state that, at any loading (load impedance Z 13 assumes the values from the interval 0 to ∞ Ohms) of the circuit 12 output, the variation of electrical load Zᵢ on the input of the circuit 12 will not manifest itself. Thus, the basic component or group of components will remain in the resonant state.

### INDUSTRIAL APPLICABILITY

The described solar element can be utilized as a harvester or generator of electric energy, possibly also as a sensor or nonlinear converter. The advantage proposed by the presented solution consists in its insensitivity to higher temperatures inside the area of the element, which is especially convenient for applications in energetics and within larger units.

### SUMMARY OF REFERENTIAL SYMBOLS

1. electromagnetic wave
2. location of wave incidence
3. incidence plane
4. basic resonator
5. dielectric structure
6. boundary of variation in material properties
7. basic resonator reflector
8. transformational component
9. connecting component of basic resonators
10. dielectric
11. free termination of the last area of tuned structures or a coupled terminating solar system
12. electric circuit
13. load
14. inductor
15. nonlinear component
16. connecting component
17. second capacitor
18. first capacitor
19. source of current or voltage caused by induction from an electromagnetic wave
20. dielectric structure of differently tuned resonators
21. relative electrode

1. A solar element including a resonator arranged on a structure, characterized in that it is formed by a layered dielectric structure consisting of an area (5) with minimum electromagnetic damping, whose upper plane constitutes the incidence plane (3), and the layered dielectric structure is permeable for an electromagnetic wave and limited by the boundaries (6) of variations in material properties, while at least one 2D-3D resonator (4) is arranged in the area (5) with minimum electromagnetic damping, wherein the 2D part of the resonator is arranged in the incidence plane (3), with the related 3D part located in the dielectric (10) whereas the area (5) with minimum electromagnetic damping is coupled with at least one area (20) having a different resonance frequency, the area (20) is limited by the boundaries (6) of variations in material properties, and at least one 2D-3D resonator (4) is arranged in the area (20) having a different resonance frequency, wherein the 2D part of the resonator (4) is arranged in the incidence plane (3), while the related 3D part is located in the dielectric (10), whereas the last area (20) having a different resonance frequency in the direction of the electromagnetic wave propagation is coupled with a solar system (11).

2. The solar element including a resonator according to claim 1, characterized in that the 2D-3D resonator (4) is formed by two parts, of which the first 2D part is constituted by a transformational element (8) arranged on the incidence plane (3) and consisting of a pair of electrodes in the form of coupled conductors, while the second 3D part is constituted by a dielectric (10) and a reflector (7), which is arranged inside the area (5) with minimum electromagnetic damping, and the transformational component (8) is arranged on the dielectric (10), with which the reflector (7) is matched.

3. The solar element including a resonator according to claim 2, characterized in that the 2D-3D resonator (4) is formed by two parts, of which the first 2D part is constituted by a transformational element (8) arranged on the incidence plane (3) and consisting of a pair of electrodes in the form of coupled conductors, while the second 3D part is constituted by a dielectric (10) and a reflector (7), which is arranged inside the area (20) with a different resonance frequency, and the transformational component (8) is arranged on the dielectric (10), with which the reflector (7) is matched.

4. The solar element including a resonator according to claim 2, characterized in that the reflector (7) is, in relation to the dielectric (10), arranged orthogonally to the incidence plane (3).

5. The solar element including a resonator according to claim 1, characterized in that the area (5) with minimum electromagnetic damping may comprise a 2D-3D resonator (4) exhibiting a resonance frequency consistent with frequency of 2D-3D resonators (4) arranged in other areas (20) with different resonance frequency within the solar system.
